(19) United States
(12) Patent Application Publication
(10) Pub. No.: US 2008/0101036 A1
(43) Pub. Date: May 1, 2008

(54) Heat-dissipating assembly structure

(76) Inventor: Chiung Yi Chen, Taipei (TW)

Correspondence Address: BIRCH STEWART KOLASCH & BIRCH, PO BOX 747, FALLS CHURCH, VA, 22040-0747, US

(21) Appl. No.: 11/586,637

(22) Filed: Oct. 26, 2006

(51) Int. Cl. H05K 7/20

(52) U.S. Cl. 361/720

(57) ABSTRACT

A heat-dissipating assembly structure is disclosed that includes a first and a second thermally conductive sheets, each of which includes a plurality of spaced fastening sections including a projection on its outer surface and two parallel guides with the projection disposed there-between; and a plurality of U-shaped clamps including two flexible latches at two opposite sides, each latch having a hook-shaped end. Attaching the first and second thermally conductive sheets to both side surfaces of a memory by adhesive respectively with the top of the memory being concealed, and pressing each of the clamps onto the corresponding fastening sections will secure the first and second thermally conductive members and the memory together by fastening the ends of the latches at the projections respectively. The heat-dissipating assembly structure of the present invention possesses an increased heat removal efficiency during operation.

### BACKGROUND OF THE INVENTION

1. Field of Invention

The present invention relates to a heat-dissipating assembly structure and more particularly to a heat-dissipating assembly structure clamped an IC (e.g., memory) with increased heat removal efficiency during operation.

2. Related Art

It is known that IC components would produce large amounts of heat during operation. The generated heat must be dissipated in order to keep the components within their safe operating temperatures. Otherwise, overheating may shorten the useful life of the components and may result in their malfunctions. For dissipating heat, a number of methods and devices have been developed. For example, there are fans for speeding up the exchange of air heated by the components (e.g., chips or hard disk) for cooling ambient air; heat sinks with increased surface area for dissipating heat; and water cooling devices.

However, the heat removal performance of fan will lower if parts of a device are arranged in close proximity or the surface area of the component to be cooled for contacting with air is few. For solving this problem, a combination of fan and heat sink has been developed. In detail, the heat sink comprises a flat base and an array of fin-like protrusions. The base of the heat sink is attached to a component (e.g., memory) having a small contact surface. The fan is mounted on the protrusions such that heat generated by the component during operation can be sufficiently dissipated through the thermally conductive protrusions.

Moreover, a conventional heat-dissipating assembly structure for a memory R is shown in FIG. 1 and comprises two thermally conductive sheets 11 attached to two opposite surfaces of the memory R by adhesive respectively. The heat-dissipating assembly structure further comprises a U-shaped clamp 10 tightly clamping the thermally conductive sheets 11 and holding on the surface of the memory. An engaging hole 111 is formed on each thermally conductive sheets 11 for engaging with a concave provided on the ends of the clamp 10.

While heat dissipation of the memory R is increased due to its tight engagement with the thermally conductive sheets 11, the total heat removal performance of the heat-dissipating assembly structure is lowered significantly due to the provision of the engaging holes 111 which result in a reduced surface area contacting with the memory. Thus, it is desirable to provide a novel heat-dissipating assembly structure having an increased surface area for heat dissipation and means for fastening thermally conductive members and memory together in order to overcome the inadequacies of the prior art and contribute significantly to the advancement of the art.

### SUMMARY OF THE INVENTION

It is therefore an object of the present invention to provide a heat-dissipating assembly structure for memory. The heat-dissipating assembly structure of the present invention can be assembled easily and quickly. Also, the heat-dissipating assembly structure of the present invention has increased heat removal efficiency during operation when compared with the prior art shown in FIG. 1.

To achieve the above and other objects, the present invention provides a heat-dissipating assembly structure comprising a first and a second thermally conductive sheets including a plurality of spaced fastening sections including a projection on its outer surface; and a plurality of U-shaped clamps each of which includes two flexible latches at two opposite sides, each latch having a hook-shaped end, whereby attaching the first and second thermally conductive sheets to both side surfaces of a memory by adhesive respectively with the top of the memory being concealed, and pressing each of the clamps onto the corresponding fastening sections will secure the first and second thermally conductive sheets and the memory together by fastening the hook-shaped ends of the latches at the projections respectively.

In one aspect of the present invention, each of the projections is formed by punching and includes an inclined surface and a flat portion.

In another aspect of the present invention, each of the fastening sections includes two parallel guides with the projection disposed there-between for guiding the pressing of the clamp and a distance between the guides is substantially conformed to the length of the clamp.

The above and other objects, features and advantages of the present invention will become apparent from the following detailed description taken with the accompanying drawings.

### BRIEF DESCRIPTION OF THE DRAWINGS

FIG. 1 is a longitudinal sectional view of a conventional heat-dissipating assembly structure mounted on a memory;

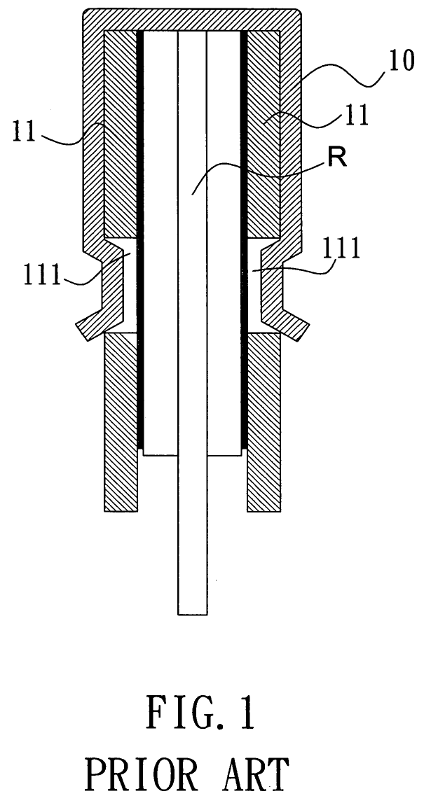

FIG. 2 is an exploded view of a preferred embodiment of heat-dissipating assembly structure according to the present invention to be mounted on a memory;

FIG. 3 is a longitudinal sectional view of the heat-dissipating assembly structure of FIG. 2 being mounted on the memory; and

FIG. 4 is a view similar to FIG. 3 where the heat-dissipating assembly structure has been mounted on the memory.

### DETAILED DESCRIPTION OF THE INVENTION

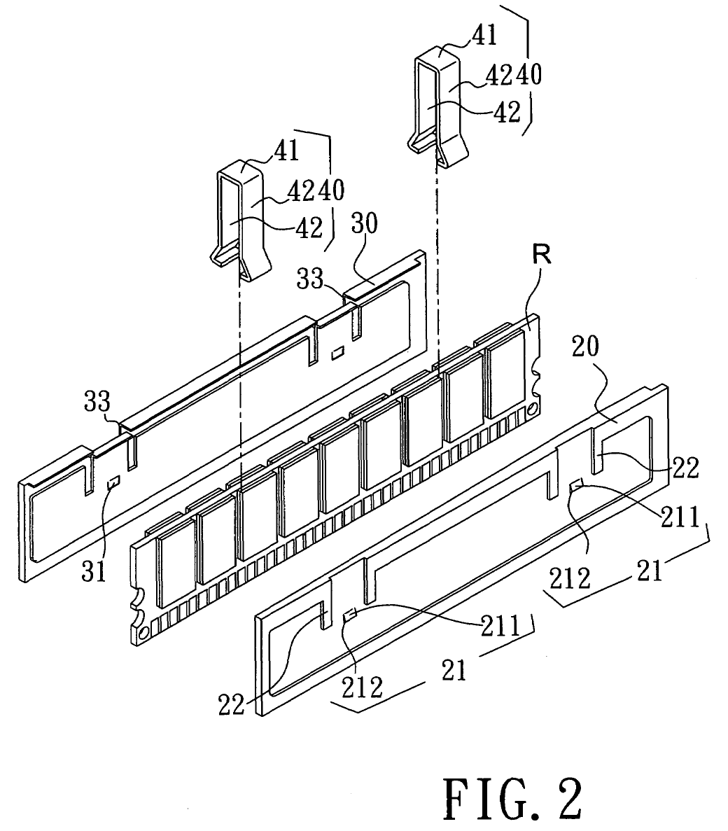

Referring to FIG. 2, a heat-dissipating assembly structure for memory R in accordance with a preferred embodiment of the present invention comprises elongate, rectangular first and second thermally conductive sheets 20 and 30 and a plurality of U-shaped clamps 40. Each component is discussed in detailed below.

The first thermally conductive sheet 20 comprises a plurality of spaced fastening sections including a projection 21 on its outer surface and two raised, parallel guides 22 with the projection 21 disposed there-between. A distance between the guides 22 is substantially conformed to the length of the clamp 40. The projection 21 comprises an inclined surface 211 and a flat portion 212.

Likewise, the second thermally conductive sheet 30 comprises a plurality of spaced fastening sections including a projection 31 on its outer surface and two raised, parallel guides 32 with the projection 31 disposed there-between. A distance between the guides 32 is substantially conformed to the length of the clamp 40. The projection 31 comprises an inclined surface 311 and a flat portion 312.

The clamp 40 is a substantially U-shaped member. The clamp 40 comprises a top sheet 41 and two latches 42 at two opposite sides respectively. The latch 42 has a hook-shaped bending end. Thus, the clamp 40 is flexible in nature. Further, a distance between both ends of the latches 42 is slightly smaller than the width of the top sheet 41.

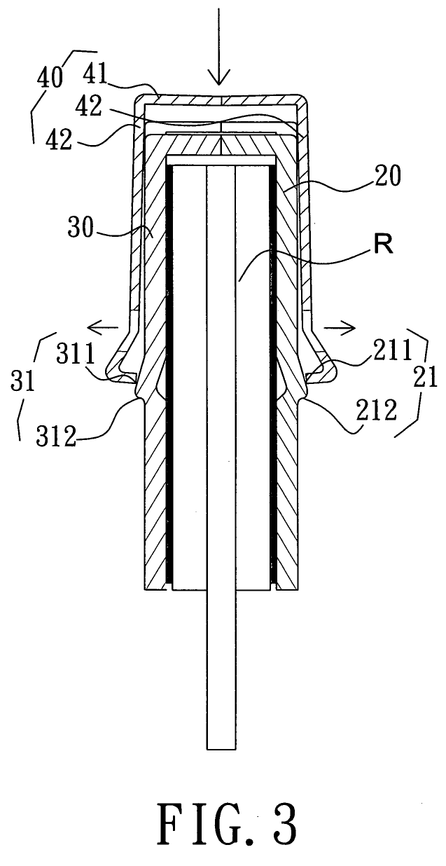

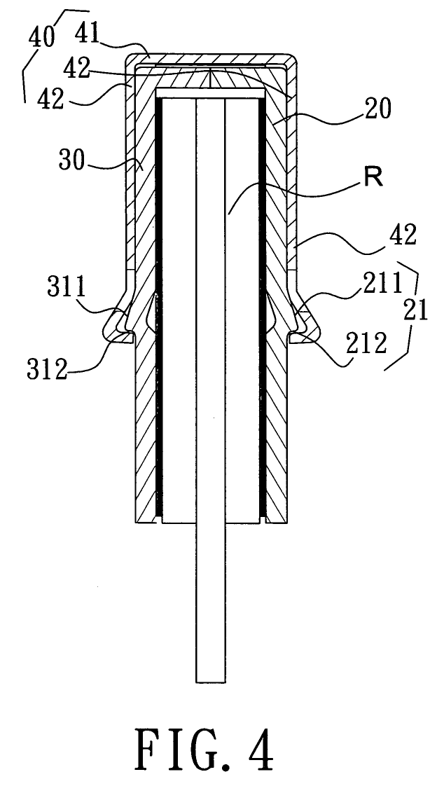

Referring to FIGS. 3 and 4, an heat-dissipating assembly structure of the invention will be described in detailed below. First, attach the thermally conductive sheets 20 and 30 to both side surfaces of the elongate, rectangular memory R by adhesive respectively. Also, a top of the memory R is concealed by the thermally conductive sheets 20 and 30. Next, align each of the clamps 40 with the pair of the fastening sections (i.e., front and rear ends of the clamp 40 line up with the two guides 22 (or 32) respectively) prior to pressing down the clamp 40 along a top of the pair of the fastening sections. The bottom opening of the clamp 40 expands outward as it encounters the top of the pair of the fastening sections (i.e., the latches 42 flex outwardly). The expansion of the clamp 40 reaches its maximum when the ends of the latches 42 encounter a joining point of the inclined surface 311 and the flat portion 312 and a joining point of the inclined surface 211 and the flat portion 212 respectively. After passing the joining points, the latches 42 suddenly contract due to flexibility to have their ends urged against the flat portions 212 and 312 respectively. As a result, the thermally conductive members 20 and 30 and the memory R are fastened by the clamps 40.

The assembly is quick. Further, it is envisaged by the present invention that a maximum contact area between the thermally conductive members 20 and 30 and the memory R is obtained, resulting in a great increase of heat removal efficiency. Note that the projections 21 and 31 can be formed by punching.

It is to be understood that the present invention is by no means limited only to the particular constructions herein disclosed and shown in the drawings, but also comprises any modifications or equivalents within the scope of the claims.

What is claimed is:

1. A heat-dissipating assembly structure comprising:
a first and a second thermally conductive sheets each including a plurality of spaced fastening sections on which outer surface a projection is provided; and
a plurality of U-shaped clamps including two flexible latches at two opposite sides, each latch having a hook-shaped end,
whereby attaching the first and second thermally conductive sheets to both side surfaces of a memory with the top of the memory being concealed, and pressing each of the clamps onto the corresponding fastening sections secures the first and second thermally conductive sheets and the memory together by fastening the ends of the latches at the projections respectively.

2. The heat-dissipating assembly structure of claim 1, wherein each of the projections is formed by punching.

3. The heat-dissipating assembly structure of claim 1, wherein each of the projections includes an inclined surface and a flat portion.

4. The heat-dissipating assembly structure of claim 1, wherein each of the fastening sections includes two parallel guides with the projection disposed there-between for guiding the pressing of the clamp.

5. The heat-dissipating assembly structure of claim 4, wherein a distance between the guides is substantially conformed to the length of the clamp.
